(19) United States
(12) Patent Application Publication
(10) Pub. No.: US 2025/0079257 A1
(43) Pub. Date: Mar. 6, 2025

(54) GALLIUM NITRIDE-BASED SEMICONDUCTOR DEVICE AND METHOD FOR MANUFACTURING THE SAME

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 18/950,404

(22) Filed: Nov. 18, 2024

Related U.S. Application Data
(63) Continuation of application No. PCT/JP2023/017246, filed on May 8, 2023.

(30) Foreign Application Priority Data
May 18, 2022 (JP) 2022-081882

(51) Int. Cl. H01L 23/373; H01L 21/02; H01L 23/15; H01L 29/20

(52) U.S. Cl. CPC H01L 23/373; H01L 21/02266; H01L 21/02422; H01L 21/0254; H01L 23/15; H10D 62/8503

(57) ABSTRACT

A gallium nitride-based semiconductor device includes an amorphous glass substrate having a first surface and a second surface opposite to the first surface; a gallium nitride-based semiconductor layer on the first surface of the amorphous glass substrate, and a compensation layer on the second surface of the amorphous glass substrate. A thermal expansion coefficient of the compensation layer is more than a thermal expansion coefficient of the amorphous glass substrate and less than a thermal expansion coefficient of the gallium nitride-based semiconductor layer.

### CROSS-REFERENCE TO RELATED APPLICATIONS

This application is a Continuation of International Patent Application No. PCT/JP2023/017246, filed on May 8, 2023, which claims the benefit of priority to Japanese Patent Application No. 2022-081882, filed on May 18, 2022, the entire contents of which are incorporated herein by reference.

### FIELD

An embodiment of the present invention relates to a semiconductor device and a method for manufacturing the same, wherein a gallium nitride-based semiconductor layer is formed on an amorphous glass substrate.

### BACKGROUND

A semiconductor stacked structure in which substrate warpage during the manufacturing process of the semiconductor stacked structure is prevented by forming a film mainly composed of Si on the back surface of a Si substrate and has a lower thermal expansion coefficient and higher Young's modulus than the Si substrate is disclosed (Japanese Unexamined Patent Application Publication No. 2012-84913). A method for manufacturing semiconductor wafers in which a SiC or GaN film is formed on a front surface of a Si substrate and a Si₃N₄ film is formed on a back surface is disclosed (Japanese Unexamined Patent Application Publication No. 2003-218031). A method for growing thin films consisting of semiconductor materials that includes forming a GaN or AlN layer on the back surface of a sapphire substrate with a GaN layer on the front surface to prevent warpage is disclosed (Japanese Unexamined Patent Application Publication No. 2005-116785).

It is known that quartz, sapphire, or the like is used as a substrate in a process of manufacturing a semiconductor device by forming a gallium nitride-based semiconductor layer on the substrate. In general, semiconductor devices have to undergo photolithography and plasma etching processes during processing and electrode formation. If the substrate of the device is warped at that time, it is expected that the characteristics and yield of the device to be manufactured are affected.

When amorphous glass is used as the substrate, it is advantageous in terms of cost because a substrate having a larger area than sapphire can be formed. However, since the substrate having such a large area is likely to be warped, it is necessary to reduce the amount of warping during device processing. Since the amount of warpage is proportional to the square of the diameter of the substrate, the occurrence of warpage is an important problem when a large-diameter substrate is used. When a gallium nitride-based semiconductor layer or the like is formed on the surface of an amorphous glass substrate, oxygen may be mixed into the gallium nitride-based semiconductor film due to degassing of H₂O or the like from the back side of the substrate.

### SUMMARY

A gallium nitride-based semiconductor device in an embodiment according to the present invention includes an amorphous glass substrate having a first surface and a second surface opposite to the first surface, a gallium nitride-based semiconductor layer on the first surface of the amorphous glass substrate, and a compensation layer on the second surface of the amorphous glass substrate. A thermal expansion coefficient of the compensation layer is more than a thermal expansion coefficient of the amorphous glass substrate and less than a thermal expansion coefficient of the gallium nitride-based semiconductor layer.

A method for manufacturing a gallium nitride-based semiconductor device in an embodiment according to the present invention, the method includes forming a compensation layer on a second surface of an amorphous glass substrate and forming a gallium nitride-based semiconductor layer on a first surface opposite to the second surface of the amorphous glass substrate. The compensation layer is formed by sputtering using a target, the target has a coefficient of thermal expansion greater than a coefficient of thermal expansion of the amorphous glass substrate and less than a coefficient of thermal expansion of the gallium nitride-based semiconductor layer.

### BRIEF DESCRIPTION OF DRAWINGS

FIG. 1 is a cross-sectional view showing the structure of a gallium nitride-based semiconductor device according to an embodiment of the present invention.

FIG. 2 is a cross-sectional view showing the structure of a gallium nitride-based semiconductor device according to an embodiment of the present invention.

FIG. 3 is a cross-sectional view of an LED as a structure of a gallium nitride-based semiconductor device according to an embodiment of the present invention.

FIG. 4 is a cross-sectional view of an LED as a structure of a gallium nitride-based semiconductor device according to an embodiment of the present invention.

FIG. 5 is a cross-sectional view of a transistor as a structure of a gallium nitride-based semiconductor device according to an embodiment of the present invention.

FIG. 6 is a cross-sectional view of a transistor as a structure of a gallium nitride-based semiconductor device according to an embodiment of the present invention.

### DESCRIPTION OF EMBODIMENTS

Hereinafter, embodiments of the present invention are described with reference to the drawings. However, the present invention can be implemented in many different aspects and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements like those described previously with respect to previous drawings may be given the same reference sign (or a number followed by a, b, etc.) and a detailed description may be omitted as appropriate.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions.

A gallium nitride-based semiconductor device according to an embodiment of the present invention will be described in detail below. Semiconductor devices may include light emitting devices such as light emitting diodes and active devices such as transistors. As specific examples of gallium nitride-based semiconductor devices, various semiconductor devices such as diodes, transistors, thyristors, light- emitting devices, light-receiving devices, high-frequency diodes, high-frequency transistors, various sensors (temperature sensors, pressure sensors, acceleration sensors, etc.), integrated circuits, and the like are exemplified. The gallium nitride-based semiconductor layer refers to a single-layer or multilayer structure of a semiconductor mainly composed of at least one layer of gallium nitride, and includes a structure in which a plurality of gallium nitride layers having different conductivity types are stacked, and a structure in which a layer of a III-V compound semiconductor having a different composition is stacked in which a predetermined element, such as indium or aluminum, is added to gallium nitride as well as gallium nitride.

### (1) Fundamental Structure

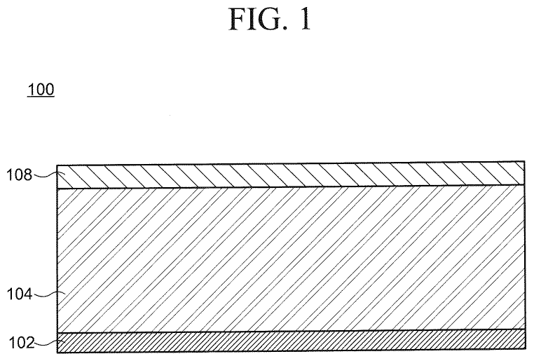

FIG. 1 shows an example of a cross-sectional structure of a gallium nitride-based semiconductor device 100 according to an embodiment of the present invention. The gallium nitride-based semiconductor device 100 has an amorphous glass substrate 104 and has a structure in which a layer including a gallium nitride-based semiconductor layer 108 formed on a first surface of the amorphous glass substrate 104 and a layer including a compensation layer 102 formed on a second surface of the amorphous glass substrate.

### (2) Amorphous Glass Substrate

The amorphous glass substrate 104 is a substrate composed of a glass material which generally does not have a crystalline structure but may have a crystalline structure in a small region. The amorphous glass substrate 104 has a first surface for the gallium nitride-based semiconductor layer 108, a second surface for the compensation layer 102, and an edge surface, and the first and second surfaces are in a front-to-back relationship.

The amorphous glass substrate 104 is preferably made of a material that does not deviate significantly from the thermal expansion coefficient of the gallium nitride-based semiconductor layer 108 to reduce warpage, which adversely affects the fabrication and patterning processes during the fabrication of semiconductor devices. As an example, the amorphous glass substrate 104 has a coefficient of thermal expansion of less than 4.2 (×10⁻⁶/K), preferably less than 4.0 (×10⁻⁶/K), greater than 3.0 (×10⁻⁶/K), and preferably greater than 3.5 (×10⁻⁶/K).

The glass material used as the amorphous glass substrate 104 is preferably made of a glass material with low alkali metal content to prevent contamination of the gallium nitride-based semiconductor layer 108 by alkali metal components generated from the glass material. As an example, the content of alkali metals in amorphous glass is 0.1 mass % or less.

As an example of the amorphous glass substrate 104, an amorphous glass material composed of aluminoborosilicate glass or aluminosilicate glass is used. Such amorphous glass materials are used in liquid crystal displays and organic electroluminescent (organic EL) displays, and large area glass substrates called mother glass are available on the market. It is possible to manufacture a gallium nitride-based semiconductor device at a low cost using a large-area substrate by selecting the amorphous glass substrate 104 as the substrate of the semiconductor device.

The amorphous glass substrate 104 is required to be resistant to the thermal hysteresis when the semiconductor device is fabricated. Accordingly, the glass-transition temperature of the amorphous glass substrate 104 is, for example, 650° C. or higher, preferably 720° C. or higher, and 900° C. or lower, preferably 810° C. or lower. For the same reason, the softening point is 900° C. or higher, preferably 950° C. or higher, and 1150° C. or lower, preferably 1050° C. or lower.

The first surface (gallium nitride-based semiconductor layer side) and the second surface (compensation layer side) of the amorphous glass substrate 104 may not have the same surface roughness. However, the surface roughness of the second surface may be made rougher than the surface roughness of the first surface from the viewpoint of preventing electrostatic damage caused by peeling electrification when the semiconductor device is taken out from various devices in the semiconductor device manufacturing process.

The thickness of the amorphous glass substrate 104 is not limited, but from the viewpoint of reducing warpage, it is preferable to use a substrate that is sufficiently thicker than the thickness of the gallium nitride-based semiconductor layer 108 formed on the first surface. As an example, the amorphous glass substrate 104 has a thickness of 50 times or more the thickness of the gallium nitride-based semiconductor layer 108. The amorphous glass substrate 104 has, for example, a thickness of 0.5 to 1.0 mm.

The mechanical strength of the amorphous glass substrate 104 is not particularly limited, but from the viewpoint of reducing warpage, it is preferable to have a Young's modulus of 70 GPa to 90 GPa as an example.

### (3) Gallium Nitride-Based Semiconductor Layer

The gallium nitride-based semiconductor layer 108 may include at least one gallium nitride layer, and, for example, the gallium nitride-based semiconductor layer 108 may be formed of a single layer of gallium nitride. The gallium nitride-based semiconductor layer 108 may include at least one layer selected from, for example, indium gallium nitride, aluminum gallium nitride or other gallium nitride-based semiconductors in addition to at least one gallium nitride layer and may have a structure in which these layers are stacked. When the gallium nitride layer is not included, a single layer or laminate of indium gallium nitride, aluminum gallium nitride layer or other gallium nitride-based semiconductor may be used. The gallium nitride layer, the indium gallium nitride layer, and the aluminum gallium nitride layer forming the gallium nitride-based semiconductor layer 108 preferably have stoichiometric compositions but may deviate from the stoichiometric compositions.

The gallium nitride-based semiconductor layer 108 preferably has crystallinity. That is, the gallium nitride-based semiconductor material constituting the gallium nitride-based semiconductor layer 108 preferably has at least crystallinity. These may be single crystals, but they may be polycrystalline, microcrystalline, or nanocrystalline. The crystal structure of the gallium nitride-based semiconductor layer 108 can have a wurtzite structure. The gallium nitride-based semiconductor material constituting the gallium nitride-based semiconductor layer 108 is preferably c-axis oriented or (111)-oriented.

The conductivity type of at least one or all the layers constituting the gallium nitride-based semiconductor layer 108 may be substantially intrinsic or may have an n-type or a p-type conductivity type. Each layer constituting the gallium nitride-based semiconductor layer 108 may contain a dopant for controlling valence electrons. An element selected from silicon (Si) and germanium (Ge) may be doped into the n-type gallium nitride-based semiconductor layer as a dopant. An element selected from magnesium (Mg), zinc (Zn), cadmium (Cd), and beryllium (Be) may be doped as a dopant in the p-type gallium nitride-based semiconductor layer. The n-type gallium nitride-based semiconductor layer preferably has a carrier concentration of 1×10¹⁸/cm³ or more, and the p-type gallium nitride-based semiconductor layer preferably has a carrier concentration of 5×10¹⁶/cm³ or more.

As an example, a sputtering deposition method can be used to form the gallium nitride-based semiconductor layer 108.

There is no limit to the thickness of the gallium nitride-based semiconductor layer 108 to be formed, and it can be set appropriately according to the structure of the semiconductor device to be fabricated. However, the film can be sufficiently thinner than the thickness of the amorphous glass substrate 104 from the viewpoint of reducing warpage, which is disadvantageous in the semiconductor device fabrication process. As an example, it may be 1/50 or less of the amorphous glass substrate 104.

### (4) Compensation Layer

The compensation layer 102 is formed on the second surface of the amorphous glass substrate 104. It is possible to reduce the warpage of the substrate which is disadvantageous when the semiconductor device is manufactured by disposing the compensation layer 102.

During depressurization and heating when forming the gallium nitride-based semiconductor layer 108, the compensation layer 102 on the second surface reduces degas such as H₂O from the second surface of the amorphous glass substrate 104, thereby reducing oxygen contamination into the gallium nitride-based semiconductor layer 108. Furthermore, it is possible to improve the resistance to a chemical treatment with acid used in the semiconductor device fabrication process, by selecting the material of the compensation layer 102 appropriately.

It is possible for the compensation layer 102 to reduce warpage of the substrate caused by the difference in thermal expansion coefficient between the amorphous glass substrate 104 and the gallium nitride-based semiconductor layer 108, by selecting a thermal expansion coefficient within a predetermined range. The thermal expansion coefficient of the compensation layer 102 is preferably greater than the thermal expansion coefficient of the amorphous glass substrate 104 and less than the thermal expansion coefficient of the gallium nitride-based semiconductor layer 108. An example of the coefficient of thermal expansion of the compensation layer 102 is more than 4.0 (×10⁻⁶/K), preferably more than 4.1 (×10⁻⁶/K), less than 5.0 (×10⁻⁶/K), preferably less than 4.6 (×10⁻⁶/K), and preferably less than 4.6 (×10⁻⁶/K).

It is possible to effectively and evenly transfer heat to the entire substrate, and as a result, the uniformity of the thickness of the gallium nitride-based semiconductor layer 108 can also be improved in the heating process when forming the gallium nitride-based semiconductor layer 108 on the amorphous glass substrate 104 since the compensation layer 102 is adjacent to the amorphous glass substrate 104, by taking the thermal conductivity to a predetermined value. Therefore, the compensation layer 102 is preferred to have a thermal conductivity that exceeds the thermal conductivity of the amorphous glass substrate 104. The thermal conductivity of the compensation layer 102 can be selected according to the material constituting the amorphous glass substrate 104, for example, the thermal conductivity exceeds 10 (W m⁻¹ K⁻¹), preferably 40 (W m⁻¹ K⁻¹).

The thermal conductivity of the compensation layer 102 can be adjusted by adjusting a film density within a predetermined range. The relationship between film density and thermal conductivity varies depending on the materials constituting the compensation layer 102, for example, the film density of the compensation layer 102 is 2.50 g/cm³ or more, preferably 2.60 g/cm³ or more, 4.10 g/cm³ or less, preferably 4.00 g/cm³ or less.

The material used for the compensation layer 102 is not limited as long as it satisfies the above-mentioned physical properties. Any material is preferable as long as it has resistance to a chemical treatment with an acid or the like used in the semiconductor device manufacturing process. The material forming the compensation layer 102 may, for example, have an aluminum nitride layer or an aluminum oxide layer, or a structure in which an aluminum nitride layer and an aluminum oxide layer are stacked.

The method of forming the compensation layer 102 is not limited and known deposition methods can be used. The compensation layer 102 is preferably formed by sputtering to avoid forming on a large-area substrate and excessively raising the temperature of the substrate. The conditions for sputtering are not particularly limited, and known sputtering equipment can be used and the conditions can be set accordingly.

The thickness of the compensation layer 102 is not limited and a thickness suitable for the structure of the device can be selected. However, from the viewpoint of reducing substrate warpage, it is preferable to form the layer so that it is not excessively thin compared to the gallium nitride-based semiconductor layer 108, and for example, it may have a thickness of 80% or more of the thickness of the gallium nitride-based semiconductor layer 108.

### (5) Buffer Layer

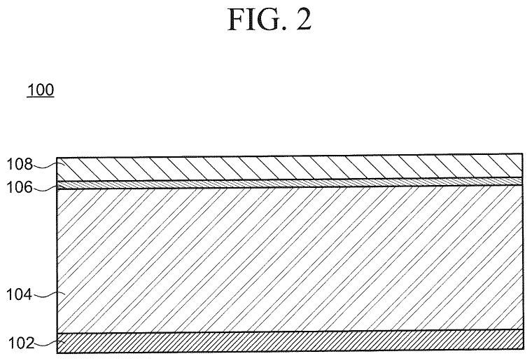

FIG. 2 shows an example of a cross-sectional structure of the gallium nitride-based semiconductor device 100 according to another embodiment of the present invention. The gallium nitride-based semiconductor device 100 has a structure with a buffer layer 106 between the first surface of the amorphous glass substrate 104 and the gallium nitride-based semiconductor layer 108, and the compensation layer 102 on the second surface. The buffer layer 106 is a layer provided to reduce the difference in thermal expansion coefficient between the amorphous glass substrate 104 and the gallium nitride-based semiconductor layer 108 and to reduce warpage of the entire gallium nitride-based semiconductor device 100.

The thermal expansion coefficient of the buffer layer 106 is preferably greater than the thermal expansion coefficient of the amorphous glass substrate 104 and less than the thermal expansion coefficient of the gallium nitride-based semiconductor layer 108. The material of the buffer layer 106 is not limited as long as the thermal expansion coefficient is in the above relationship, for example, aluminum nitride may be used.

### (6) Other Configurations

The semiconductor device according to one embodiment of the present invention is not limited to the above configuration. Other elements can be added as needed according to the design of the semiconductor device.

Although not shown in the figure, a structure may be added between the amorphous glass substrate 104 and the gallium nitride-based semiconductor layer 108 to form an underlying insulating layer to prevent diffusion of alkali metal components and other elements from the amorphous glass substrate 104 to the gallium nitride-based semiconductor layer 108. The underlying insulating layer may be a single layer or a multilayer structure, and an inorganic insulating film such as a silicon nitride film, silicon oxide film, silicon oxynitride film, aluminum nitride film, aluminum oxide film, or aluminum oxynitride film may be used as one example.

To reduce the lattice mismatch between the amorphous glass substrate 104 and the gallium nitride-based semiconductor layer 108, an orientation control layer may be disposed. The orientation control layer has a crystal structure with c-axis orientation, which enables crystallization of the gallium nitride-based semiconductor layer 108. In other words, the orientation control layer has a c-axis orientation and a crystalline surface having six-fold rotational symmetry, such as a hexagonal-most-dense structure or a face-centered cubic structure, so that the orientation can be controlled so that the c-axis of the gallium nitride-based semiconductor layer 108 grows in the film thickness direction (perpendicular to the first plane of the amorphous glass substrate 104). In this embodiment, the buffer layer 106 also functions as an orientation control layer. Although not shown in the figure, an orientation control layer different from the buffer layer 106 may be separately disposed between the buffer layer 106 and the gallium nitride-based semiconductor layer 108.

### (7) Manufacturing of Semiconductor Devices

An example of a manufacturing process for the gallium nitride-based semiconductor device 100 according to an embodiment of the present invention is described below. The compensation layer 102 is formed on the second surface of the amorphous glass substrate 104 by sputtering. Thereafter, when necessary, the buffer layer 106 is formed on the first surface. Next, one or more gallium nitride-based semiconductor layers that constitute the gallium nitride-based semiconductor layer 108 are formed on the first surface of the amorphous glass substrate 104 by sputtering. Electrodes on the gallium nitride-based semiconductor device 100 are formed by depositing electrodes using vacuum evaporation or other known techniques, followed by photolithography and plasma etching processes, after the gallium nitride-based semiconductor layer 108 is formed.

When the compensation layer 102 is formed by sputtering, for example, the temperature (set temperature) during deposition is controlled at 100° C. to 600° C., preferably 400° C. to 600° C. As an example, aluminum nitride and/or aluminum oxide are used as the sputtering target. The gas (sputter gas) introduced during sputter deposition is, for example, argon (Ar) or a mixture of argon (Ar) and nitrogen (N₂). As the sputtering apparatus, for example, a dipole sputtering apparatus, a magnetron sputtering apparatus, a dual magnetron sputtering apparatus, a facing target sputtering apparatus, an ion-beam sputtering apparatus, an inductively coupled plasma (ICP) sputtering apparatus, or the like can be used.

When layers of different compositions, such as an aluminum oxide layer and an aluminum nitride layer, for example, are stacked as the compensation layer 102, sputtering targets of different compositions can be used for each, and continuous deposition can be performed in a vacuum by using a multi-chamber sputtering apparatus.

When the gallium nitride-based semiconductor layer 108 is deposited by sputtering, the sputtering apparatus and conditions are not particularly limited, and a known sputtering apparatus can be used, and the conditions can be set as needed. As an example, the substrate temperature (set temperature) during deposition is controlled to 100° C. to 600° C., preferably 400° C. to 600° C. To form the gallium nitride-based semiconductor layer 108 by sputtering, a sintered gallium nitride-based semiconductor material is used as the sputtering target. Argon (Ar) or a mixture of argon (Ar) and nitrogen (N₂) is used as the gas (sputter gas) introduced during sputtering deposition. As sputtering apparatus, a dipole sputtering apparatus, magnetron sputtering apparatus, dual magnetron sputtering apparatus, facing target sputtering apparatus, ion-beam sputtering apparatus, inductively coupled plasma (ICP) sputtering apparatus, etc. can be used.

When layers of different compositions, such as gallium nitride, indium gallium nitride, and aluminum gallium nitride layers, are stacked as the gallium nitride-based semiconductor layer 108, the sputtering targets with different compositions are used for each, and for example, continuous deposition can be performed in a vacuum by using a multi-chamber sputtering system.

The following describes some specific configurations of the gallium nitride-based semiconductor device 100 according to an embodiment of the present invention. The gallium nitride-based semiconductor device according to an embodiment of the present invention is not limited to the specific examples of semiconductor devices described in the following examples.

### First Embodiment

### 1-1. Light Emitting Diode: LED

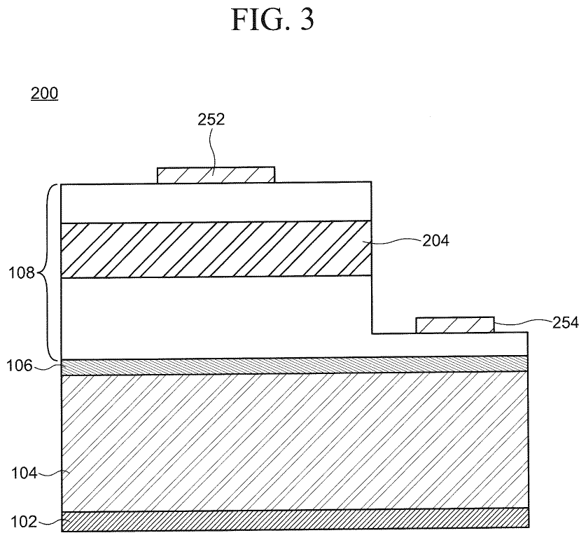

FIG. 3 shows the schematic of an LED 200 as an example of a gallium nitride-based semiconductor device according to one embodiment of the present invention. The LED 200 includes a compensation layer 102 which is disposed on a second surface of an amorphous glass substrate 104 and includes a buffer layer 106 and a gallium nitride-based semiconductor layer 108 disposed on a first surface of the amorphous glass substrate 104 as necessary. The gallium nitride-based semiconductor layer 108 may include a plurality of layers including a light-emitting layer 204, and may optionally include, for example, an n-type gallium nitride-based semiconductor layer, a p-type gallium nitride-based semiconductor layer, and an undoped gallium nitride-based semiconductor layer composed of an undoped gallium nitride-based semiconductor.

The structure of the light-emitting layer 204 is not particularly limited, and the structure of the light-emitting layer using a known gallium nitride-based semiconductor, which is used as an LED device, can be used. As an example, it can be formed by a quantum well structure in which gallium nitride layers and indium gallium nitride layers are alternately stacked.

When an n-type gallium nitride-based semiconductor layer is included, the material is not particularly limited, for example, a layer composed of a gallium nitride-based semiconductor doped with silicon (Si) can be formed. Similarly, when a p-type gallium nitride-based semiconductor layer is included, the material is not particularly limited, for example, a layer composed of a gallium nitride-based semiconductor doped with magnesium (Mg) can be formed.

When a plurality of layers having different compositions are laminated as the gallium nitride-based semiconductor layer 108, the gallium nitride-based semiconductor layer can be fabricated by using sputtering targets corresponding to the respective compositions.

The LED 200 may include, for example, a p-type electrode 252 and an n-type electrode 254 formed on the gallium nitride-based semiconductor layer 108. As the p-type electrode 252 and the n-type electrode 254, known electrode materials can be used, for example, metal materials including aluminum (Al), gold (Au) and silver (Ag), and platinum metals such as palladium (Pd) and indium (In) can be used. The method of forming the p-type electrode 252 and the n-type electrode 254 is not particularly limited, and a known film deposition method can be used, for example, it can be formed by vacuum deposition using a resistive heating evaporation source or a high-frequency induction heating evaporation source using the metal material for the electrode.

### 1-2. Fabrication of LED

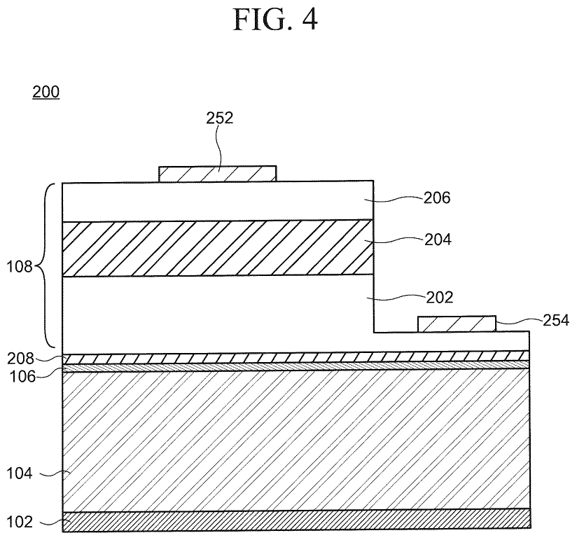

FIG. 4 shows a specific example of a method for fabricating the LED 200 for a semiconductor device according to an embodiment of the present invention. The amorphous glass substrate 104, which is configured with aluminosilicate glass and has a larger surface roughness on the second surface than on the first surface is prepared. The compensation layer 102 composed of aluminum nitride or the like is formed by sputtering on the second surface of the amorphous glass substrate 104.

The buffer layer 106 configured from aluminum nitride or the like is subsequently formed on the first surface of amorphous glass substrate 104. Next, an undoped gallium nitride layer 208 and a Si-doped gallium nitride layer 202 are formed by sputtering. In addition, an indium gallium nitride layer and a gallium nitride layer are formed by sputtering as the light-emitting layer 204, and a Mg-doped gallium nitride layer 206 is formed thereon by sputtering.

Then, after patterning by photolithography and plasma etching, an n-type electrode 254 configured with indium on the Si-doped gallium nitride layer 202 and a p-type electrode 252 configured by palladium and gold (The Pd/Au stacking structure shown in FIG. 4.) is formed on the Mg-doped gallium nitride layer 206, respectively, by vacuum evaporation.

### Second Embodiment

### 2-1. Transistor

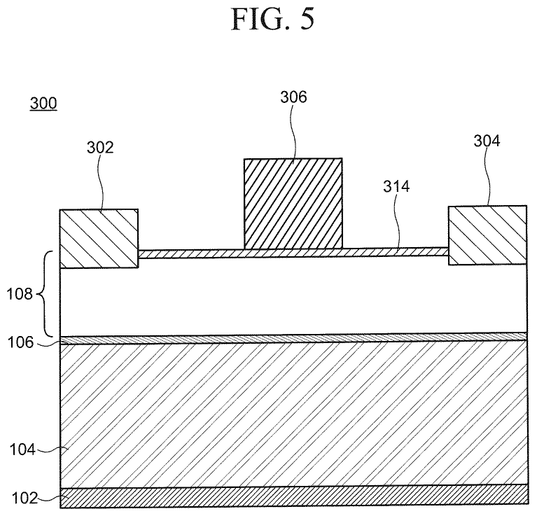

FIG. 5 shows a schematic of a transistor 300 as an example of a gallium nitride-based semiconductor device according to an embodiment of the present invention. The transistor 300 includes the compensation layer 102 on the second side of amorphous glass substrate 104, the buffer layer 106, a gallium nitride-based semiconductor layer 108, and a gate insulating layer 314 on the first side of amorphous glass substrate 104. The gallium nitride-based semiconductor layer 108 may include a plurality of layers and may include the n-type gallium nitride-based semiconductor layer, the p-type gallium nitride-based semiconductor layer, and the undoped gallium nitride-based semiconductor layer, as an example.

The transistor 300 may include a source electrode 302, a drain electrode 304, and a gate electrode 306 formed on the gallium nitride-based semiconductor layer 108. Although known electrode materials may be used as the source electrode 302, the drain electrode 304, and the gate electrode 306, for example, metal materials including aluminum (Al), nickel (Ni), titanium (Ti), gold (Au) and silver (Ag), and platinum group metals such as palladium (Pd) and indium (In) can be used as electrode materials. The source electrode, the drain electrode, and the gate electrode can be prepared, for example, by vacuum evaporation using a resistive heating evaporation source or a high-frequency induction heating evaporation source using metal materials for the electrodes.

### 2-2. Fabrication of Transistor

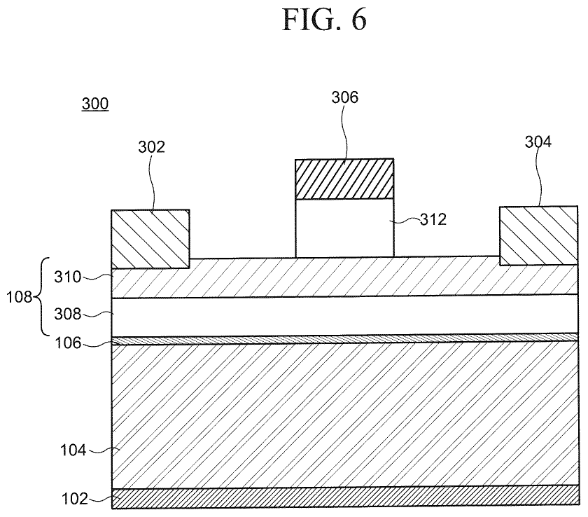

FIG. 6 shows a specific example of the fabrication of the transistor 300 for a semiconductor device according to an embodiment of the present invention. The amorphous glass substrate 104, which is configured of aluminosilicate glass and has a larger surface roughness on the second surface than on the first surface is prepared. The compensation layer 102 configured of aluminum nitride or the like is formed by sputtering on the second surface of the amorphous glass substrate 104.

Next, aluminum nitride as the buffer layer 106 is formed on the first surface of the amorphous glass substrate 104. Next, an undoped gallium nitride layer 308, an undoped gallium aluminum nitride layer 310, and an Mg-doped gallium nitride layer 312 are formed by sputtering.

Then, a gate electrode 306 configured by a gold layer and a nickel layer (The Au/Ni stacked structure shown in FIG. 6.) is formed by vacuum evaporation, and the gate electrode 306 and Mg-doped gallium nitride layer 312 are formed by photolithography and plasma etching. The source electrode 302 is configured by a stacked structure (The Au/Ti/Al/Ti stacked structure shown in FIG. 6.) formed by gold, titanium, and aluminum layers and the drain electrode 304 configured by a stacked structure (The Au/Ti/Al/Ti stacked structure shown in FIG. 6.) formed by gold, titanium, and aluminum layers are formed on the undoped gallium nitride aluminum layer 310 by vacuum evaporation and these electrodes are processed by photolithography and plasma etching.

The semiconductor device which includes LEDs and transistors according to an embodiment of the present invention can be fabricated on the amorphous glass substrate 104 because the warpage of the amorphous glass substrate 104 is greatly reduced, so that the gallium nitride-based semiconductor device can still be fabricated on the amorphous glass substrate 104 after the photolithography and plasma etching processes.

Furthermore, the semiconductor device according to an embodiment of the present invention is provided with the compensation layer 102 with excellent thermal conductivity on the amorphous glass substrate 104, so that heat can be efficiently transferred during heating in the gallium nitride-based semiconductor layer fabrication process, thereby improving the uniformity and other conditions of the film to be formed.

Furthermore, the presence of the compensation layer 102 also reduces the amount of H₂O and other degas from the back side of the substrate, which reduces oxygen contamination into the gallium nitride-based semiconductor layer 108 and further improves the condition of the film to be formed. Furthermore, the use of aluminum nitride or aluminum oxide as the compensating layer 102 greatly improves the resistance to acid and other chemical treatments, which can greatly improve the manufacturing yield of semiconductor devices.

The semiconductor devices according to an embodiment of the present invention can be used to stabilize the characteristics of various devices and improve manufacturing yields.

Each of the embodiments described above as an embodiment of the present invention may be combined as appropriate, as long as they do not contradict each other. Based on each embodiment, any addition, deletion, or design modification of configuration elements, or any addition, omission, or modification of conditions of a process by a person skilled in the art is also included in the scope of the present invention, as long as it has the gist of the invention.

It is understood that other advantageous effects different from the advantageous effects caused by each of the above-described embodiments, which are obvious from the description herein or which can be easily foreseen by those skilled in the art, will naturally be brought about by the present invention.

What is claimed is:

1. A gallium nitride-based semiconductor device, comprising:
an amorphous glass substrate having a first surface and a second surface opposite to the first surface;
a gallium nitride-based semiconductor layer on the first surface of the amorphous glass substrate; and
a compensation layer on the second surface of the amorphous glass substrate,
wherein a thermal expansion coefficient of the compensation layer is more than a thermal expansion coefficient of the amorphous glass substrate and less than a thermal expansion coefficient of the gallium nitride-based semiconductor layer.

2. The gallium nitride-based semiconductor device according to claim 1, wherein a thermal conductivity of the compensation layer is more than a thermal conductivity of the amorphous glass substrate.

3. The gallium nitride-based semiconductor device according to claim 1, wherein the compensation layer includes either one or both of an aluminum oxide and an aluminum nitride.

4. The gallium nitride-based semiconductor device according to claim 1, wherein a thickness of the compensation layer is 80% or more of a thickness of the gallium nitride-based semiconductor layer, and a thickness of the amorphous glass substrate is 50 times or more of the thickness of the gallium nitride-based semiconductor layer.

5. The gallium nitride-based semiconductor device according to claim 1, further comprising a buffer layer between the first surface of the amorphous glass substrate and the gallium nitride-based semiconductor layer.

6. The gallium nitride-based semiconductor device according to claim 1, wherein the compensation layer is formed on the amorphous glass substrate by sputtering.

7. A method for manufacturing gallium nitride-based semiconductor device, the method comprising:
forming a compensation layer on a second surface of an amorphous glass substrate; and
forming a gallium nitride-based semiconductor layer on a first surface opposite to the second surface of the amorphous glass substrate,
wherein the compensation layer is formed by sputtering using a target, the target has a coefficient of thermal expansion greater than a coefficient of thermal expansion of the amorphous glass substrate and less than a coefficient of thermal expansion of the gallium nitride-based semiconductor layer.

8. The method for manufacturing gallium nitride-based semiconductor device according to claim 7, wherein the compensation layer is formed by sputtering using an aluminum oxide and/or an aluminum nitride as a target.

9. The method for manufacturing gallium nitride-based semiconductor device according to claim 7, wherein the compensation layer is formed by sputtering at 100° C. to 600° C.
